(19) United States
(12) Patent Application Publication
(10) Pub. No.: US 2003/0013223 A1
(43) Pub. Date: Jan. 16, 2003

(54) Structure and method for fabricating semiconductor structures and devices utilizing the formation of a compliant III-V arsenide nitride substrate used to form the same

(75) Inventors: Jamal Ramdani, Chandler, AZ (US); Lyndee L. Hilt, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/904,892

(22) Filed: Jul. 16, 2001

(51) Int. Cl. H01L 21/00

(52) U.S. Cl. 438/46; 438/47

(57) ABSTRACT

High quality epitaxial layers of monocrystalline III-V arsenide nitride materials can be grown overlying monocrystalline substrates such as large silicon wafers by forming a compliant substrate for growing the monocrystalline layers. One way to achieve the formation of a compliant substrate includes first growing an accommodating buffer layer on a silicon wafer. The accommodating buffer layer is a layer of monocrystalline oxide spaced apart from the silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline III-V arsenide nitride material layer. Any lattice mismatch between the accommodating buffer layer and the underlying silicon substrate is taken care of by the amorphous interface layer. In addition, an accommodating buffer layer comprising a barium strontium titanium oxide and a monocrystalline III-V arsenide nitride layer, such as GaAsN, having a nitrogen concentration ranging from 1-5% function to further reduce any lattice mismatch between layers.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer comprised of a III-V arsenide nitride semiconductor material. More particularly, the invention is directed to the one step formation of a compliant substrate containing a GaAsN material system on a silicon substrate.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

Long wavelength devices, such as those which allow for emission at 1.3 micrometers, are of great importance in the data and telecommunications industries. Accordingly, there is a need for simple, controllable long wavelength optoelectronic devices that can be produced at low cost. The standard material used for long wavelength optoelectronic devices in current data and telecommunication applications is a GaInAs based system that is lattice matched to a InP substrate. In order to reduce costs, the monolithic integration of long wavelength devices with silicon circuitry will be of great importance. Accordingly, a need exists for a compliant, high quality monocrystalline compound semiconductor material that can be formed on a silicon substrate.

The present invention is directed to a process for forming a compliant substrate containing a III-V arsenide nitride, and particularly a GaAsN material system, on a silicon substrate and its resulting semiconductor structure. The resulting semiconductor structure can then be used in the formation of long wavelength optoelectronic devices such as, for example, LEDs and LDs.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIG. 17 illustrates schematically, in cross-section, the formation of a device structure in accordance with still another embodiment of the invention;

FIG. 18 illustrates schematically, in cross-section, the formation of yet another embodiment of a device structure in accordance with the invention; and

FIG. 19 illustrates schematically in cross-section, the formation of still another embodiment of a device structure in accordance with the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a unit cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements and typically have a perovskite crystalline structure. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

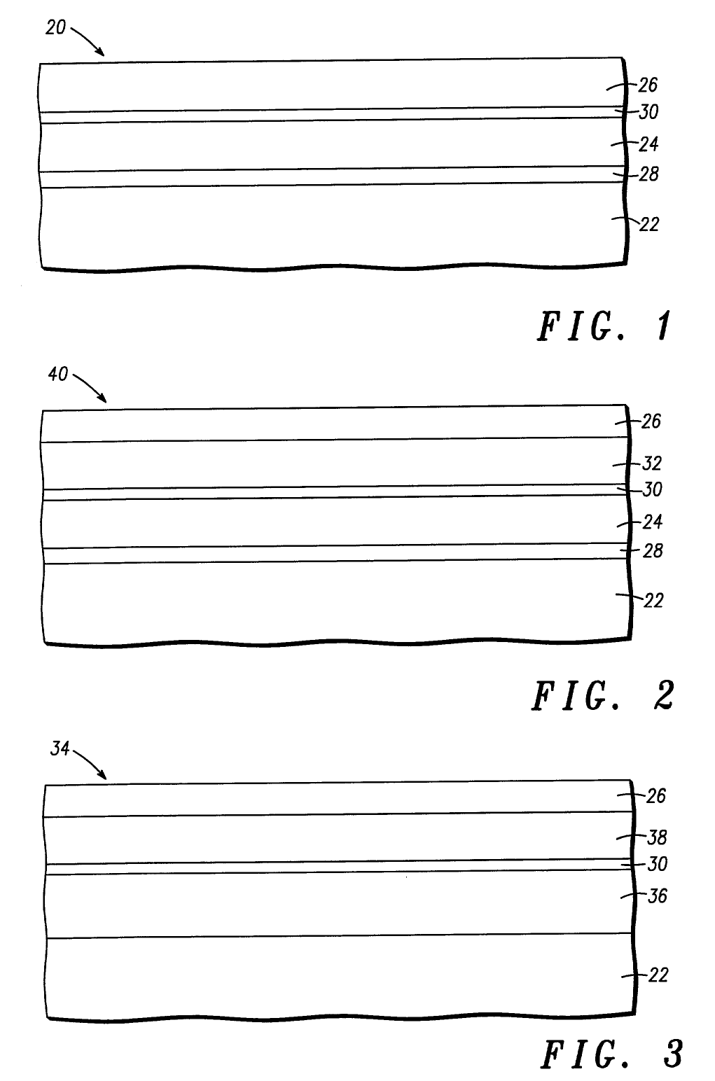

FIG. 3 schematically illustrates, in cross section, a portion of a semiconductor structure 34 in accordance with another exemplary embodiment of the invention.

Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate.

However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ.) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

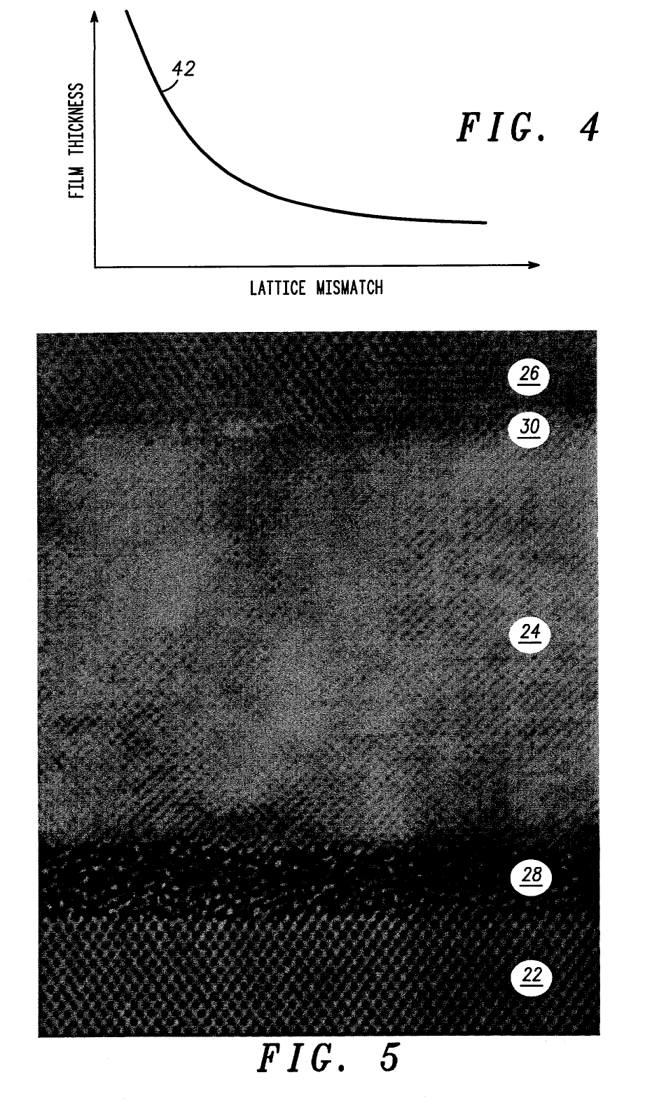

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the 20 subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

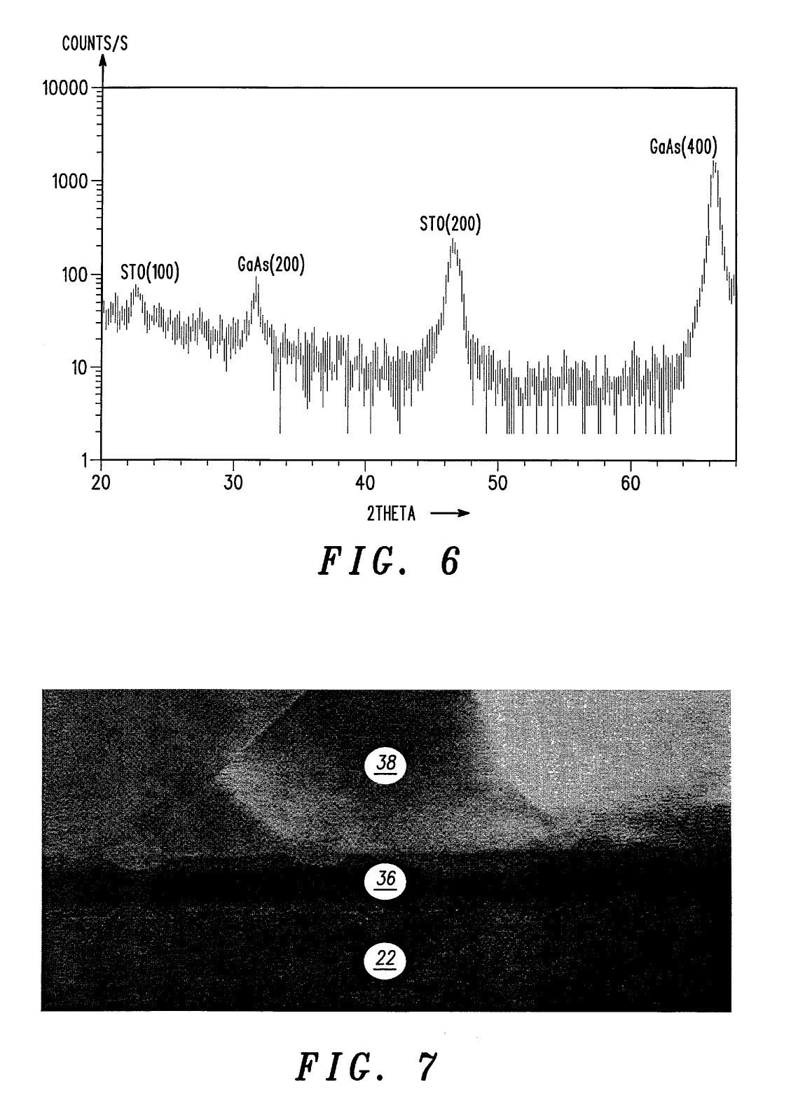

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

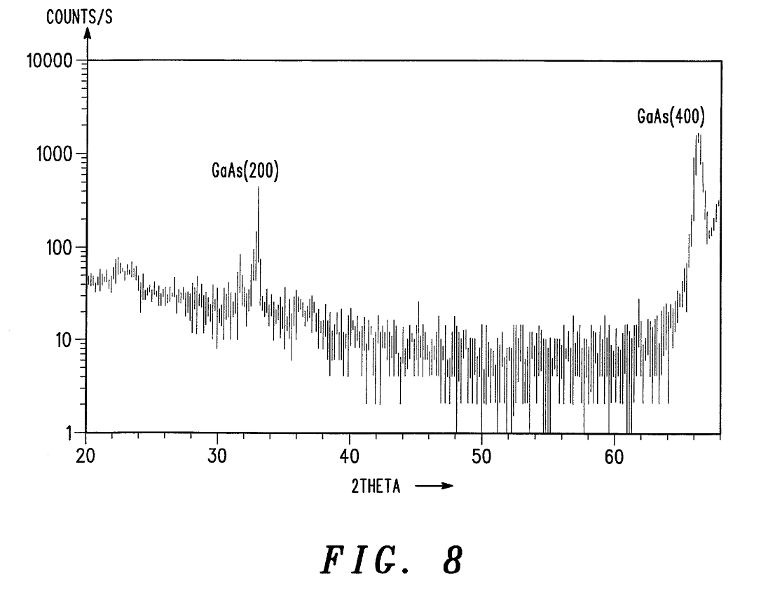

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and III-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference to layer 24 in FIGS. 1-2 and any of those compounds previously described with reference to layer 36 in FIG. 3 which is formed from layers 24 and 28 referenced in FIGS. 1 and 2.

Layer 54 is grown with a barium (Ba) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, gallium (Ga) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAsN, is then deposited via MBE, CVD, MOCVD, MEE, ALE, PVD, CSD, PLD, and the like to form the final structure illustrated in FIG. 12.

The monocrystalline GaAsN layer 66 having a nitrogen concentration within a range of about 1-5% is directly grown on accommodating buffer layer 54. The orientation of monocrystalline GaAsN layer 66 is rotated by 45 degrees with respect to accommodating buffer layer 54 in order to match the crystal lattice constants of the two materials.

As previously stated, it is theoretically possible to grow an infinitely thick, high quality epitaxial monocrystalline layer 66 on a host crystal such as accommodating buffer layer 54 when there is no lattice mismatch. However, as the mismatch in lattice constants increases, the thickness of an achievable, high quality monocrystalline layer decreases rapidly. For example, if the lattice constants between accommodating buffer layer 54 and monocrystalline material layer 66 are mismatched by more than about 2%, monocrystalline epitaxial layers in excess of about 2 nm cannot be achieved.

In this embodiment, the addition of nitrogen to GaAs to form monocrystalline GaAsN layer 66 lowers the lattice constant of the GaAsN material thereby decreasing any mismatch between monocrystalline GaAsN layer 66 and accommodating buffer layer 54 when the orientation of monocrystalline GaAsN layer 66 is rotated by 45 degrees. A 2% nitrogen concentration in the monocrystalline GaAsN layer 66 will result in only a 1.5% mismatch between monocrystalline GaAsN layer 66 and accommodating buffer layer 54, while a 3% nitrogen concentration in the monocrystalline GaAsN layer 66 will result in less than a 1% mismatch between monocrystalline GaAsN layer 66 and accommodating buffer layer 54. This combination will lead to a decrease in the formation of dislocations in the monocrystalline GaAsN layer 66. Moreover, as preferably described with reference to this embodiment, the addition of Ba to accommodating buffer layer 54 comprising a strontium titanium oxide leads to perfect lattice matching between monocrystalline GaAsN layer 66 and accommodating buffer layer 54.

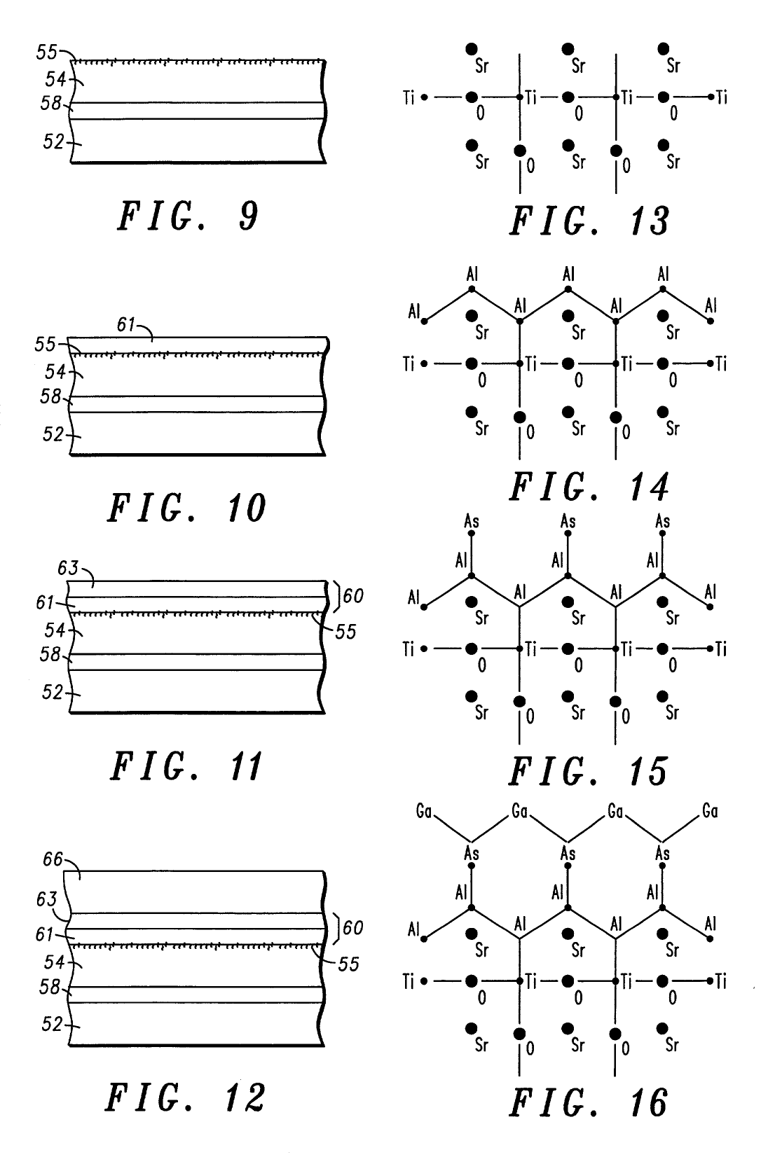

FIGS. 13-16 illustrate possible molecular bond structures for a GaAsN compound semiconductor structure formed in accordance with the embodiment of the invention illustrated in FIGS. 9-12. More specifically, FIGS. 13-16 illustrate the growth of GaAsN (layer 66) on the barium terminated surface of a barium strontium titanate monocrystalline oxide (layer 54) using a surfactant containing template (layer 60).

The growth of a monocrystalline material layer 66 such as GaAsN on an accommodating buffer layer 54 such as a barium strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAsN layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAsN layer.

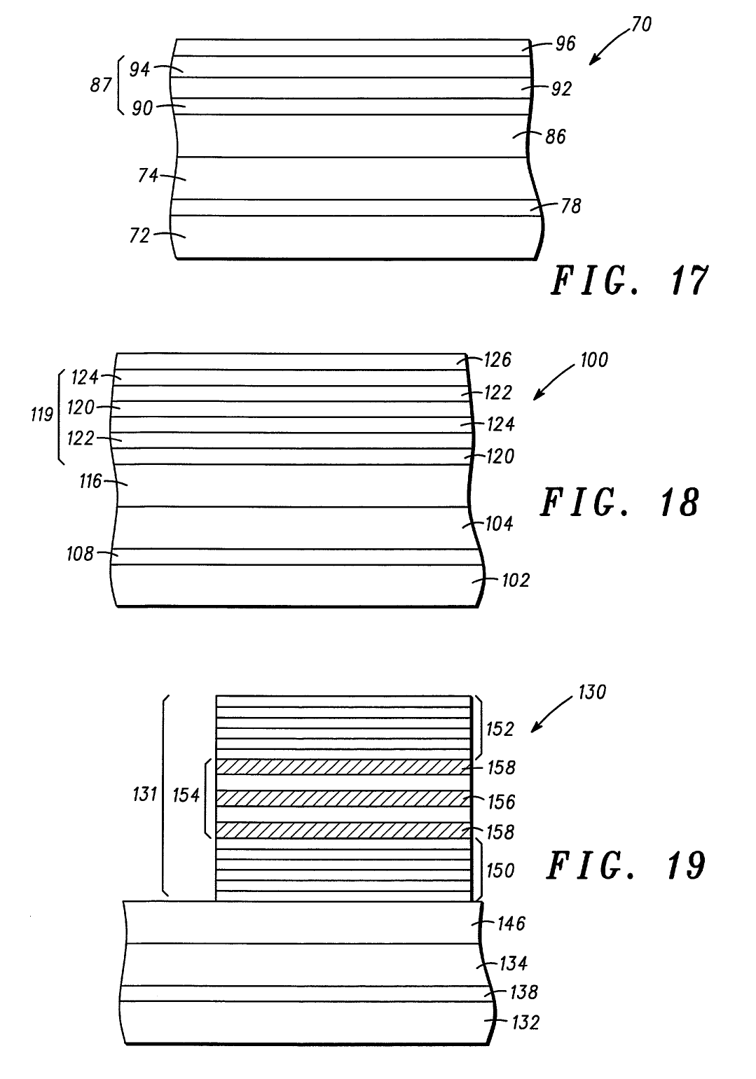

FIG. 13 illustrates the molecular bond structure of a barium terminated surface of a barium strontium titanate monocrystalline oxide layer. A gallium or aluminum surfactant layer is deposited on top of the barium terminated surface and bonds with that surface as illustrated in FIG. 14, which reacts to form a capping layer comprising a monolayer of Ga₂Ba having the molecular bond structure illustrated in FIG. 14 which forms a diamond-like structure with an sp³ hybrid terminated surface that is compliant with compound semiconductors such as GaAsN. The structure is then exposed to As to form a layer of GaAs as shown in FIG. 15. The GaAs layer is then nitridated and GaAsN is then deposited to complete the molecular bond structure illustrated in FIG. 16 which has been obtained by 2D growth. The GaAsN can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with gallium.

As previously described with reference to FIG. 3, accommodating buffer layer 54 and amorphous interface layer 58 may be exposed to an anneal process sufficient to change the crystalline structure of accommodating buffer layer 54 from monocrystalline to amorphous, thereby forming an amorphous layer such that the combination of amorphous interface layer 58 and the resulting amorphous accommodating buffer layer 54 from a single amorphous oxide layer. Monocrystalline GaAsN layer 66 is then subsequently grown over surfactant containing template layer 60. Alternatively, the anneal process may be carried out subsequent to growth of layer 66.

In accordance with one aspect of this embodiment, the single amorphous oxide layer described above is formed by exposing substrate 52, accommodating buffer layer 54, amorphous interface layer 58, and template layer 60 to a rapid thermal anneal process with a peak temperature of about 700 degrees C. to about 1000 degrees C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form template layer 60. When conventional thermal annealing is employed to form a single amorphous oxide layer, an overpressure of one or more constituents of layer 60 may be required to prevent degradation of layer 66 during the anneal process. For example, when layer 66 includes GaAsN, the anneal environment preferably includes an overpressure of arsenic to mitigate degradation of layer 66.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template is used for the monolithic integration of a monocrystalline material layer such as a layer comprising GaAsN to form long wavelength optoelectronic devices.

Turning now to FIG. 17, a device structure 70 in accordance with still another embodiment of the invention is illustrated in cross-section. This embodiment comprises a p-i-n diode 87 which utilizes the formation of a compliant substrate which relies on the epitaxial growth of a single crystal oxide on silicon followed by the epitaxial growth of GaAsN.

An accommodating buffer layer 74 such as a monocrystalline oxide layer is first grown on a substrate layer 72, such as silicon, with an amorphous interface layer 78. Monocrystalline oxide layer 74 may be comprised of any of those materials previously discussed with reference to layer 24 in FIGS. 1 and 2, but preferably comprises a barium strontium titanium oxide, while amorphous interface layer 78 is preferably comprised of any of those materials previously described with reference to layer 28 illustrated in FIGS. 1 and 2. Substrate 72, although preferably silicon, may also comprise any of those materials previously described with reference to substrate 22 in FIGS. 1-3.

Monocrystalline GaAsN layer 86 is formed in accordance with the methods previously described with reference to FIGS. 9-12 and serves as a template for forming a monocrystalline GaAsN p-i-n diode 87 overlying monocrystalline oxide layer 74. The GaAsN p-i-n diode 87 comprises a first GaAsN layer 90 doped with an n-type dopant, such as n-AlGaAsN for example, which underlies a second undoped GaAsN layer 92, which underlies a third AlGaAsN layer 94 doped with a p-type dopant, such as p-AlGaAsN for example. A contact layer 96 is deposited over p-i-n diode 87 and may comprise any suitable conductive material.

A device structure 100 in accordance with yet another embodiment of the invention is illustrated in cross-section in FIG. 18. This embodiment comprises a quantum well structure 119 formed on a compliant GaAsN substrate 116 formed in accordance with the present invention which can be repeated one or more times to form a multiple quantum well structure.

First, a substrate layer 102 is provided, such as silicon, and an accommodating buffer layer 104, such as a monocrystalline oxide layer, is grown on substrate layer 102 with an amorphous interface layer 108. Accommodating buffer layer 104 preferably comprises a monocrystalline layer of Sr_{z}Ba_{1-z}TiO₃ where z ranges from 0 to 1. However, layer 104 may also comprise any of those compounds previously described with reference to layer 24 in FIGS. 1 and 2 and layer 36 in FIG. 3 which is formed from layers 24 and 28 referenced in FIGS. 1 and 2. Amorphous interface layer 108 is preferably comprised of any of those materials previously described with reference to layer 28 shown in FIGS. 1 and 2.

Like GaAsN layer 86 in FIG. 17, monocrystalline GaAsN layer 116 is formed in accordance with the method previously described with reference to FIGS. 9-12 and serves as a template for forming monocrystalline quantum well structure 119. Quantum well (QW) structure 119 comprises an n-typeGaAsN cladding layer 120, which preferably comprises an AlGaAsN layer doped with an n-type dopant, an active InGaAsN layer 124 sandwiched between two undoped AlGaAsN barrier layers 122, all overlying layer 120, and a p-type GaAsN cladding layer 121, preferably comprising an AlGaAsN layer doped with a p-type dopant, overlying the upper barrier layer of the two barrier layers 122 sandwiching active layer 124. Finally, a heavily doped p-type GaAsN layer 126 is deposited over p-type cladding layer 121 to function as a contacting layer. Further, active InGaAsN layer 124 preferably comprises an indium concentration of up to about 40%.

As previously stated, QW structure 119 may be repeated one or more times to form a multiple quantum well structure. The above described structure can be used for forming long wavelength laser diodes or light emitting diodes having wavelengths within a range of about 1.3 to 1.55 microns.

Turning now to FIG. 19, a device structure 130 in accordance with another embodiment of the invention is illustrated in cross-section. Device structure 130 comprises a vertical cavity surface emitting laser (VCSEL) 131 formed on a compliant GaAsN substrate formed in accordance with the present invention.

VCSEL 131 includes bottom mirror layers 150, a laser cavity region 154, and an upper mirror layers 152. Laser cavity region 154 includes oxide layers 158 separated by a gain region 156. VCSEL 131 is formed by epitaxially growing lower mirror layers 150, laser cavity region 154 layers, and upper mirror layers 152 over a monocrystalline GaAsN layer 146. Monocrystalline GaAsN layer 146 is grown on a monocrystalline oxide layer 134 which is grown on a substrate layer 132, such as silicon, with an amorphous interface layer 138 formed between oxide layer 134 and substrate 132.

Monocrystalline GaAsN layer 146 is formed in accordance with the methods previously described with reference to FIGS. 9-12. Monocrystalline oxide layer 134 may comprise any of those compounds previously described with reference to layer 24 in FIGS. 1 and 2 and layer 36 in FIG. 3 but preferably comprises a monocrystalline layer of Sr_{z}Ba_{1-z}TiO₃ where z ranges from 0 to 1.

Structure 130 may also include various devices such as CMOS circuits formed within monocrystalline layer 146 and/or substrate layer 132.

Lower mirror layers 150 include alternating layers of GaAsN compound semiconductor materials. For example, the first, third and fifth films within the optical laser may comprise GaAsN, and the second, fourth, and sixth films within lower mirror layers 150 may comprise AlGaAsN or vice versa.

Upper mirror layers 152 are formed in a similar manner to lower mirror layers 150 and also include alternating films of GaAsN compound semiconductor materials. In one particular embodiment, upper mirror layers 152 may be p-type doped GaAsN materials, such as p-type AlGaAsN for example, and lower mirror layers 150 may be n-type doped GaAsN materials, such as n-type AlGaAsN, and each layer within mirror layers 150 and 152 have a thickness of about lambda/4 where lambda is the wavelength of light emitted from the laser source.

The present invention provides for the monolithic integration of III-V arsenide nitrides and silicon devices to form long wavelength optoelectronic devices. The present invention further provides one step formation of a compliant GaAsN material on a silicon substrate thereby enabling the creation of simple and controllable long wavelength optoelectronic devices at reduced cost. The process of forming the compliant GaAsN substrate relies on the epitaxial growth of single crystal oxides on silicon followed by the epitaxial growth of single crystal thin GaAsN with nitrogen concentration ranging from 1-5% to allow for better lattice matching between the single crystal oxide and GaAsN layers with a band gap of less than 1 eV.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating a monocrystalline GaAsN layer which can be used to form semiconductor structures, devices and integrated circuits which may include other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor structure comprising:
a monocrystalline silicon substrate;
an amorphous oxide material overlying the monocrystalline silicon substrate;
a monocrystalline perovskite oxide material overlying the amorphous oxide material; and
a monocrystalline III-V arsenide nitride compound semiconductor material overlying the monocrystalline perovskite oxide material.

2. The semiconductor structure of claim 1 wherein the monocrystalline semiconductor substrate comprises a layer of a material comprising silicon.

3. The semiconductor structure of claim 2 wherein the amorphous oxide layer comprises a silicon oxide.

4. The semiconductor structure of claim 1 further comprising a template layer between the monocrystalline oxide layer and the monocrystalline III-V arsenide nitride compound semiconductor layer.

5. The semiconductor structure of claim 4 wherein said template layer comprises a surfactant layer and a capping layer.

6. The semiconductor structure of claim 5 wherein the surfactant layer comprises a material from the group consisting of Al, In, and Ga.

7. The semiconductor structure of claim 5 wherein the surfactant layer is exposed to a halogen to form the capping layer.

8. The semiconductor structure of claim 7 wherein the halogen comprises a material from the group consisting of As, P, Sb and N.

9. The semiconductor substrate of claim 5 wherein the surfactant layer comprises a thickness of about 1 to 2 monolayers.

10. The monocrystalline semiconductor structure of claim I wherein the monoerystalline oxide layer comprises SrₓBa₁₋ₓTiO₃ where x ranges from 0 to 1.

11. The semiconductor structure of claim 1 wherein the amorphous oxide layer and the monocrystalline oxide layer has a thickness of about 2-10 nm.

12. The semiconductor structure of claim 1 further comprising a buffer layer between the monocrystalline oxide layer and the monocrystalline III-V arsenide nitride compound semiconductor layer.

13. The semiconductor structure of claim 12 wherein the buffer layer comprises a layer of semiconductor material.

14. The semiconductor structure of claim 1 wherein the monocrystalline III-V arsenide nitride compound semiconductor layer comprises GaAsN.

15. The semiconductor structure of claim 1 further comprising a first active semiconductor device formed on or at least partially in the monocrystalline III-V arsenide nitride compound semiconductor layer.

16. The semiconductor structure of claim 15 wherein the first active semiconductor device comprises an optical device.

17. The semiconductor structure of claim 16 wherein the optical device comprises a p-i-n diode.

18. The semiconductor structure of claim 17 wherein the p-i-n diode comprises an n-type cladding layer comprising an n-doped AlGaAsN material, and active layer comprising an InGaAsN material, and a p-type cladding layer comprising a p-doped AlGaAsN material.

19. The semiconductor structure of claim 16 wherein the optical device comprises a multiple quantum well structure for at least one of a light emitting diode and a laser diode which is capable of emitting wavelengths in a range of about 1.3 to 1.55 microns.

20. The semiconductor structure of claim 16 wherein the optical device comprises a VCSEL.

21. The semiconductor structure of claim 1 wherein the monocrystalline oxide layer comprises an amorphous silicate.

22. The semiconductor structure of claim 21 wherein the monocrystalline oxide material is subsequently heat treated to convert the monocrystalline oxide to an amorphous oxide.

23. The semiconductor structure of claim 1 wherein the monocrystalline oxide material is subsequently heat treated to convert the monocrystalline oxide to an amorphous oxide.

24. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate; and
epitaxially forming a monocrystalline III-V arsenide nitride compound semiconductor layer overlying the monocrystalline perovskite oxide film.

25. The process of claim 24 wherein the step of forming an amorphous oxide interface layer comprises the step of diffusing oxygen through the perovskite oxide film layer to oxidize the monocrystalline silicon substrate.

26. The process of claim 24 wherein the step of depositing a perovskite oxide film comprises the steps of:
growing an epitaxial perovskite oxide film by a process selected from MBE, MOCVD, MEE, and ALE; and
after the step of epitaxially forming a monocrystalline III-V arsenide nitride compound semiconductor layer, thermally annealing the perovskite oxide film to convert the epitaxial oxide film to an amorphous layer.

27. The process of claim 24 wherein the step of providing a monocrystalline silicon substrate comprises providing a monocrystalline silicon substrate having a silicon oxide layer on a surface thereof.

28. The process of claim 27 wherein the step of forming a perovskite oxide film comprises the steps of:
reacting a material selected from SrₘBa₁₋ₘ where m ranges from 0 to 1 and SrₙBaₙ₋₁O where n ranges from 0 to 1 with the silicon oxide layer to form a template on the silicon substrate surface;
epitaxially depositing a monocrystalline layer comprising SrₓBa₁₋ₓTiO₃ where x ranges from 0 to 1 on the template; and
after the step of epitaxially forming a monocrystalline III-V arsenide mitride compound semiconductor layer, thermally annealing the monocrystalline layer comprising SrₓBa₁₋ₓTiO₃ to convert the layer to an amorphous layer.

29. The process of claim 24 further comprising the step of forming a first active semiconductor device on or at least partially in the monocrystalline III-V arsenide nitride compound semiconductor layer.

30. The process of claim 29 wherein the step of forming a first active semiconductor device comprises the step of forming an optical device.

31. The process of claim 30 wherein the step of forming an optical device comprises the step of forming a p-i-n diode.

32. The process of claim 31 wherein the step of forming the p-i-n diode comprises the steps of:
forming an n-type cladding layer comprising an n-doped AlGaAsN material;
forming an active layer comprising an InGaAsN layer over the n-type cladding layer; and
forming a p-type cladding layer comprising a p-doped AlGaAsN material over the active layer.

33. The process of claim 30 wherein the step of forming an optical device comprises the step of forming a multiple quantum well structure for at least one of a light emitting diode and a laser diode having the capability of emitting a wavelength in a range of about 1.3 to 1.55 microns.

34. The process of claim 30 wherein the step of forming an optical device comprises the step of forming a VCSEL.

35. The process of claim 24 wherein the step of forming a monocystalline III-V arsenide nitride compound semiconductor layer comprises the steps of:
depositing a surfactant on a barium terminated surface of the perovskite oxide film;
exposing the resulting surfactant containing layer to arsenic to form a GaAs template layer; and
nitridating the GaAs layer to form a GaAsN layer.

36. The process of claim 35 further comprising the step of growing the GaAsN layer to a desired thickness for forming at least one of a semiconductor structure, device and integrated circuit.

37. The process of claim 35 wherein the step of depositing a surfactant comprises the step of depositing gallium or aluminum.

38. The process of claim 35 wherein a single amorphous oxide layer is formed between the silicon substrate and the template layer.

39. The process of claim 35 wherein the step of forming the single amorphous oxide layer comprises the step of exposing the silicon substrate, the perovskite oxide film, the amorphous oxide interface layer, and the template layer to a rapid thermal annealing process.

40. The process of claim 39 further comprising the step of providing an overpressure of arsenic during the anneal process to prevent degradation of the monocrystalline III-V arsenide nitride compound semiconductor.
